(19) United States
(12) Patent Application Publication
(10) Pub. No.: US 2026/0066806 A1
(43) Pub. Date: Mar. 5, 2026

(54) SYSTEMS AND METHODS FOR A COOLING MODULE FOR AN INVERTER FOR AN ELECTRIC VEHICLE

(71) Applicant: BorgWarner Inc., Auburn Hills, MI (US)

(72) Inventor: Edward Choi, Lake Orion, MI (US)

(73) Assignee: BorgWarner Inc., Auburn Hills, MI (US)

(21) Appl. No.: 18/819,815

(22) Filed: Aug. 29, 2024

(51) Int. Cl. H02M 7/00; H05K 7/20

(52) U.S. Cl. CPC H02M 7/003; H05K 7/209

(57) ABSTRACT

A system may include an inverter configured to convert DC power from a battery to AC power to drive a motor. The inverter of the system may further include a first power module and a first cooling module configured to extract heat from the first power module. The first cooling module may further include a substrate including a first contact area for the first power module, and a plating layer on the substrate. The plating layer may be removed from the first contact area of the substrate using laser ablation.

### TECHNICAL FIELD

Various embodiments of the present disclosure relate generally to a cooling module for an inverter, and more specifically, to systems and methods of laser ablating plating on a cooling module.

### BACKGROUND

Thermal management is considered a key technical aspect in an electric vehicle system. A cooling module may therefore be a critical component in an inverter system, which controls the performance and efficiency of an overall driving system of an electric vehicle. However, some cooling modules may have reduced thermal performance and/or efficiency due to plating applied to protect the cooling module from corrosion and erosion.

The present disclosure is directed to overcoming one or more of these above referenced challenges.

### SUMMARY OF THE DISCLOSURE

In some aspects, the techniques described herein relate to a system including an inverter configured to convert DC power from a battery to AC power to drive a motor, wherein the inverter includes: a first power module; and a first cooling module configured to extract heat from the first power module, wherein the first cooling module includes: a substrate including a first contact area for the first power module, and a plating layer on the substrate, wherein the plating layer is removed from the first contact area of the substrate using laser ablation.

In some aspects, the techniques described herein relate to a system, wherein the first cooling module further includes: a thermal interface material between the first power module and the first contact area of the substrate.

In some aspects, the techniques described herein relate to a system, wherein: the thermal interface material includes a solder layer, and the plating layer provides a solder stop for the solder layer.

In some aspects, the techniques described herein relate to a system, wherein the first cooling module further includes: a second contact area for a second power module, wherein the plating layer is removed from the second contact area of the substrate using laser ablation.

In some aspects, the techniques described herein relate to a system, wherein the first contact area is separated from the second contact area by the plating layer.

In some aspects, the techniques described herein relate to a system, wherein the first cooling module further includes: a third contact area for a third power module, a fourth contact area for a fourth power module, a fifth contact area for a fifth power module, and a sixth contact area for a sixth power module, wherein the plating layer is removed from each of the third contact area, the fourth contact area, the fifth contact area, and the sixth contact area of the substrate using laser ablation.

In some aspects, the techniques described herein relate to a system, wherein the substrate includes copper and the plating layer includes nickel.

In some aspects, the techniques described herein relate to a system, wherein: the inverter further includes: a second cooling module; a second power module; and a third power module, the first cooling module is provided on a first side surface of the first power module, a first side surface of the second power module, and a first side surface of the third power module, and the second cooling module is provided on a second side surface of the first power module, a second side surface of the second power module, and a second side surface of the third power module.

In some aspects, the techniques described herein relate to a system, wherein the plating layer is not removed from the first contact area of the substrate using selective plating.

In some aspects, the techniques described herein relate to a system, wherein the plating layer protects the substrate from corrosion.

In some aspects, the techniques described herein relate to a system, further including: the battery configured to supply the DC power to the inverter; and the motor configured to receive the AC power from the inverter to drive the motor, wherein the system is provided as a vehicle including the inverter, the battery, and the motor.

In some aspects, the techniques described herein relate to a system including a cooling module configured to extract heat from a power module, wherein the cooling module includes: a substrate including a contact area for a power module, and a plating layer on the substrate, wherein the plating layer is removed from the contact area of the substrate using laser ablation.

In some aspects, the techniques described herein relate to a system, wherein the cooling module is maintained at a temperature below 150 degrees Celsius during the laser ablation.

In some aspects, the techniques described herein relate to a system, wherein a surface roughness of the substrate in the contact area is less than 2 micrometers.

In some aspects, the techniques described herein relate to a system, wherein the cooling module further includes: a solder layer on the contact area of the substrate, wherein the plating layer provides a solder stop for the solder layer.

In some aspects, the techniques described herein relate to a method including: applying a plating layer to a surface of a substrate of a cooling module; and removing, using laser ablation, a first portion of the plating layer from the substrate to expose a first contact area of the substrate for mounting a first power module to the first contact area.

In some aspects, the techniques described herein relate to a method, further including: applying a sinter layer to the first contact area.

In some aspects, the techniques described herein relate to a method, further including: applying the sinter layer to the first contact area without applying a protection layer to the first contact area.

In some aspects, the techniques described herein relate to a method, further including: mounting the first power module to the sinter layer.

In some aspects, the techniques described herein relate to a method, further including: removing, using laser ablation, a second portion of the plating layer from the substrate to expose a second contact area of the substrate for mounting a second power module to the second contact area, wherein the first contact area is separated from the second contact area by the plating layer.

Additional objects and advantages of the disclosed embodiments will be set forth in part in the description that follows, and in part will be apparent from the description, or may be learned by practice of the disclosed embodiments. The objects and advantages of the disclosed embodiments will be realized and attained by means of the elements and combinations particularly pointed out in the appended claims.

It is to be understood that both the foregoing general description and the following detailed description are exemplary and explanatory only and are not restrictive of the disclosed embodiments, as claimed.

### BRIEF DESCRIPTION OF THE DRAWINGS

The accompanying drawings, which are incorporated in and constitute a part of this specification, illustrate various exemplary embodiments and together with the description, serve to explain the principles of the disclosed embodiments.

FIG. 1 depicts an exemplary system infrastructure for a vehicle including an inverter, according to one or more embodiments.

FIG. 2 depicts an exemplary cooling module with laser ablated plating, according to one or more embodiments.

FIG. 3A depicts an exemplary cooling assembly including a first cooling module, a power module, and a thermal interface material (TIM) layer, according to one or more embodiments.

FIG. 3B depicts the cooling assembly of FIG. 3A with a second cooling module, according to one or more embodiments.

FIG. 4 depicts an exemplary three-phase double-sided cooling assembly including a plurality of power modules, according to one or more embodiments.

### DETAILED DESCRIPTION OF EMBODIMENTS

Both the foregoing general description and the following detailed description are exemplary and explanatory only and are not restrictive of the features, as claimed. As used herein, the terms “comprises,” “comprising,” “has,” “having,” “includes,” “including,” or other variations thereof, are intended to cover a non-exclusive inclusion such that a process, method, article, or apparatus that comprises a list of elements does not include only those elements, but may include other elements not expressly listed or inherent to such a process, method, article, or apparatus. In this disclosure, unless stated otherwise, relative terms, such as, for example, “about,” “substantially,” and “approximately” are used to indicate a possible variation of ±10% in the stated value. In this disclosure, unless stated otherwise, any numeric value may include a possible variation of ±10% in the stated value.

The terminology used below may be interpreted in its broadest reasonable manner, even though it is being used in conjunction with a detailed description of certain specific examples of the present disclosure. Indeed, certain terms may even be emphasized below; however, any terminology intended to be interpreted in any restricted manner will be overtly and specifically defined as such in this Detailed Description section. For example, in the context of the disclosure, the power module may be described as a device, but may refer to any device for controlling the flow of power in an electrical circuit. For example, a power module may be a metal-oxide-semiconductor field-effect transistor (MOSFETs), bipolar junction transistor (BJTs), insulated-gate bipolar transistor (IGBTs), or relays, for example, or any combination thereof, but are not limited thereto.

Thermal management may be considered a key technical aspect in an electric vehicle system. A cooling module may therefore be a critical component in a traction inverter system, which controls the performance and efficiency of an overall driving system of an electric vehicle. Therefore, improved thermal management with high performance cooling modules may be a demanding technology for performance and reliability of traction inverters. However, some cooling modules have a plating, e.g., a nickel plating, applied to the substrate to protect the coolant channels. The plating applied to a substrate is not compatible with the soldering and/or sintering between the power module and cooling module. Because of this, different methods have been developed to overcome this issue. For example, selective plating is used to expose the bare substrate material of the cooling module in certain areas. However, some methods of selective plating may have a long process time, higher costs, and reduction in thermal performance.

Laser ablation is a technology of material (e.g., paint, rust, etc.) removal from a solid surface and uses high energy, continuous or pulsed, laser beam to generate localized heat on target material surface. Then, the target material is vaporized from the solid surface. An open atmosphere may be used if oxidation is not an issue or an inert atmosphere (e.g., argon, argon CO2, or N2) may be used to reduce oxidation.

One or more embodiments may include a cooling module with a full plating that is selectively laser ablated. One or more embodiments may provide a quicker and more affordable process for preparing a cooling module. One or more embodiments may provide a more precise, e.g., better dimensionally controlled, substrate exposure for soldering areas. One or more embodiments may improve thermal performance by reducing thermal resistance. One or more embodiments may provide a solder stop around the exposed substrate to reduce hard TIM solder bleeding on a cooling module. One or more embodiments provide a cooling module without an applied protection layer, e.g., Organic Solderability Preservative (OSP).

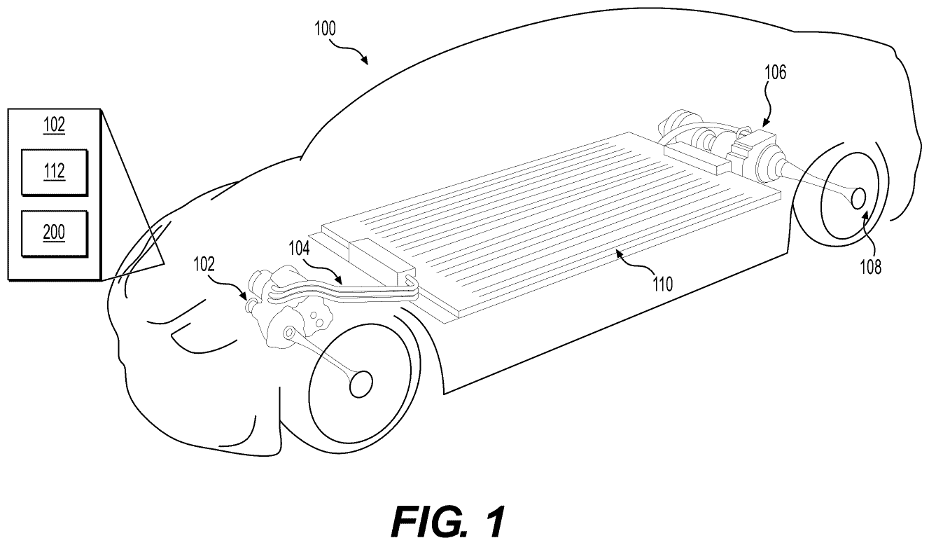

FIG. 1 depicts an exemplary system infrastructure for a vehicle including an inverter, according to one or more embodiments. Electric vehicle 100 may include traction inverter 102, connectors 104, drive motor 106, wheels 108, and battery 110. Traction inverter 102 may include power module 112 and cooling module (e.g., a heat sink system) 200. Cooling module 200 may be used to cool power module 112. Connectors 104 may connect the traction inverter 102 and battery 110. Traction inverter 102 may include components to receive electrical power from an external source and output electrical power to charge battery 110 of electric vehicle 100. Traction inverter 102, through the use of a power module 112, may convert DC power from battery 110 in electric vehicle 100 to AC power, to power the drive motor 106 and wheels 108 of electric vehicle 100, for example, but the embodiments are not limited thereto. The traction inverter 102 may be bidirectional, and may convert DC power to AC power, or convert AC power to DC power, such as during regenerative braking, for example. Traction inverter 102 may be a single-phase inverter, or a multi-phase inverter, such as a three-phase inverter, for example.

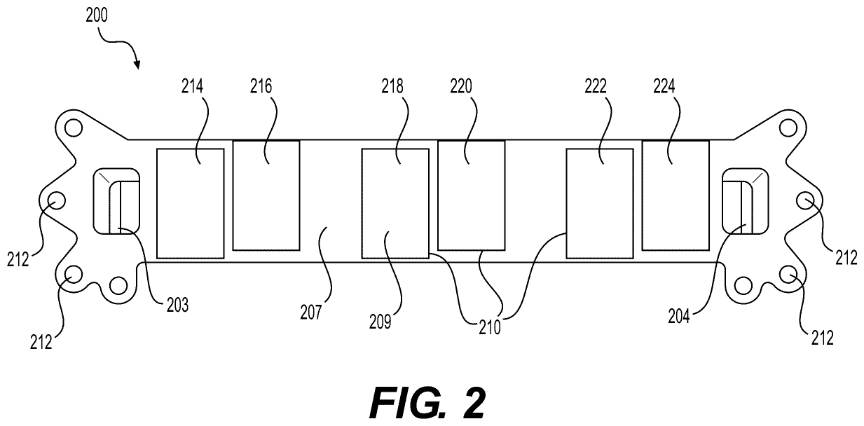

FIG. 2 depicts an exemplary cooling module with laser ablated plating, according to one or more embodiments. A cooling module may also be referred to as a heat sink. Cooling module 200 may include an inlet port 203, an outlet port 204, a plating layer 207, a substrate 209, a plurality of contact areas 214, 216, 218, 220, 222, and 224, walls 210 respectively surrounding the contact areas 214, 216, 218, 220, 222, and 224, and a plurality of holes 212.

The inlet port 203 of the cooling module 200 may be configured to supply a refrigerant (e.g. liquid coolant) to the cooling module 200. The outlet port 204 of the cooling module 200 may be configured to exhaust the refrigerant (e.g., liquid coolant) from the cooling module 200. The refrigerant used in the cooling module 200 may include a circulating fluid of liquid (e.g., liquid coolant) or gas therein, but embodiments are not limited thereto. The cooling module 200 may also include a plurality of holes 212 that receive fasteners (e.g., bolts, screws, etc.) to secure cooling module 200. In some embodiments, cooling module 200 may be secured by other fasteners, such as epoxy, adhesive, clamps, etc.

The cooling module 200 may include a substrate 209 covered in a plating layer 207. The plating layer 207, as depicted in FIG. 2, may have a plurality of contact areas 214, 216, 218, 220, 222, and 224 to expose the substrate 209 for a power module to be mounted (e.g., soldered or sintered) onto the cooling module 200 and contact the substrate 209. The cooling module 200 may be configured to provide thermal heat dissipation to (e.g., extract heat from) the power module 112 (e.g., see FIG. 1). The substrate 209 of the cooling module 200 may be selected based on a required thermal performance needed to extract heat from the power module 112. For example, the substrate 209 of the cooling module 200 may include an aluminum alloy having a high thermal conductivity, but embodiments are not limited thereto. For example, the substrate 209 of the cooling module 200 may include copper, but embodiments are not limited thereto. The plating layer 207 of the cooling module 200 may be selected based on a resistance of the plating layer 207 to environmental factors to protect the cooling module 200. For example, the plating layer 207 may be made of nickel, but embodiments are not limited thereto. In some aspects, plating layer 207 may be made of gold, silver, tin, zinc, or any combination thereof. The plating layer 207 may be made of any material that is resistant to corrosion and/or is durable.

In a selective plating method, tape is applied to the substrate when plating the cooling module such that the plating is not applied to certain areas (e.g., one or more contact areas) of the substrate. The tape blocks the plating from being applied and allows for the substrate to be exposed in desired locations. The present disclosure describes one or more embodiments in which cooling module 200 does not use selective plating. For example, the plating layer 207 is not removed from the substrate 209 at the plurality of contact areas 214, 216, 218, 220, 222, and 224 using selective plating. Instead, the present disclosure contemplates entirely covering substrate 209 with plating layer 207 and then laser ablating the plating layer 207 to remove plating layer 207 to expose the plurality of contact areas 214, 216, 218, 220, 222, and 224.

As depicted in FIG. 2, contact areas 214, 216, 218, 220, 222, and 224 may include a first contact area 214, a second contact area 216, a third contact area 218, a fourth contact area 220, a fifth contact area 222, and a sixth contact area 224. The contact areas depicted in FIG. 2 are not meant to be limiting, and any number of contact areas is contemplated herein. The contact areas 214, 216, 218, 220, 222, and 224 may be separated from one another. In other words, the plating layer 207 may be provided between the walls 210 of one contact area (e.g., first contact area 214) and another contact area (e.g., second contact area 216). As depicted in FIG. 2, the contact areas 214, 216, 218, 220, 222, and 224 are distinct and do not overlap.

Laser ablation may be used to remove the plating layer 207 to expose the bare substrate 209. Specifically, the laser ablation uses a high-energy laser beam that is either continuous or pulsed to generate localized heat on a target material surface (e.g., the plating layer 207). The target material is then vaporized from the solid surface (e.g., the substrate 209). Laser ablation may provide a more precise and repeatable dimension control for the contact areas 214, 216, 218, 220, 222, and 224. For example, the dimensions of the plurality of contact areas 214, 216, 218, 220, 222, and 224 created by laser ablating the plating layer 207 may be precisely defined so that each cutout has the same dimensions. Generally, laser ablation applied to plating layer 207 allows for strict dimensional control that can be adjusted for different applications.

Additionally, the remaining plating layer 207 may act as a solder stop, which may reduce hard TIM solder or sinter (or any kind of adhesive) bleeding onto the cooling module 200. The solder or sinter (or adhesive) layer of the TIM applied to the substrate 209 at contact areas 214, 216, 218, 220, 222, and 224 may stay within the dimensional constraints of contact areas 214, 216, 218, 220, 222, and 224 due to the solder or sinter layer not bonding with the plating layer 207 and/or due to the laser ablation etching into the plating layer 207 to expose substrate 209 and creating walls 210 (e.g., due to the depth difference) surrounding the contact areas 214, 216, 218, 220, 222, and 224.

The laser system used for the laser ablation may be configured to ablate (e.g., remove) only the plating layer 207 material and not the substrate 209 material even if the laser is applied directly to the substrate 209. Because of this, a feedback signal is not generated and a feedback controller is not needed. The laser cannot ablate material deeper than the surface of the substrate 209, so the system can utilize an open feedback loop instead of a closed feedback loop. The laser system may be configured to recognize the position of the cooling module 200 and to automatically ablate certain sections of the plating layer 207 (e.g., to create contact areas 214, 216, 218, 220, 222, and 224) based on, for example, a provided reference point. The laser system may be configured to recognize the color of the plating layer 207 and the color of the substrate 209. More specifically, the laser system may be configured to recognize the difference in color between plating layer 207 and substrate 209 so the laser system can ablate material when applied to the color of the plating layer 207 and to not ablate material when applied to the color of the substrate 209. The surface roughness of the substrate 209 may be low because the laser ablation process accurately removes only the plating layer 207 and not the surface of the substrate 209. For example, the surface roughness of the substrate may be less than approximately 500 nanometers. The surface roughness of the substrate may be less than approximately 100 nanometers. Generally, the surface roughness of the substrate may be less than 2 micrometers.

The laser ablation process applied to cooling module 200 may be completed efficiently by reducing the cost and time associated with applying the plating layer 207 to the substrate 209. In selective plating, one or more protective layers and/or coatings, such as Organic Solderability Preservative (OSP) are applied to prevent oxidization. In one or more embodiments of the present disclosure, the solder or sinter layer is applied to contact areas 214, 216, 218, 220, 222, and 224 without applying a protection layer (e.g., OSP). The laser ablation process described herein may also be applied to cooling module 200 at a low temperature. For example, the heat sink system may be maintained at or below a temperature of approximately 80 degrees Celsius during the laser ablation. In some aspects, the temperature during the laser ablation may be from approximately 60 degrees Celsius to approximately 90 degrees Celsius. Generally, the heat sink system may be maintained at or below a temperature of approximately 150 degrees Celsius during the laser ablation.

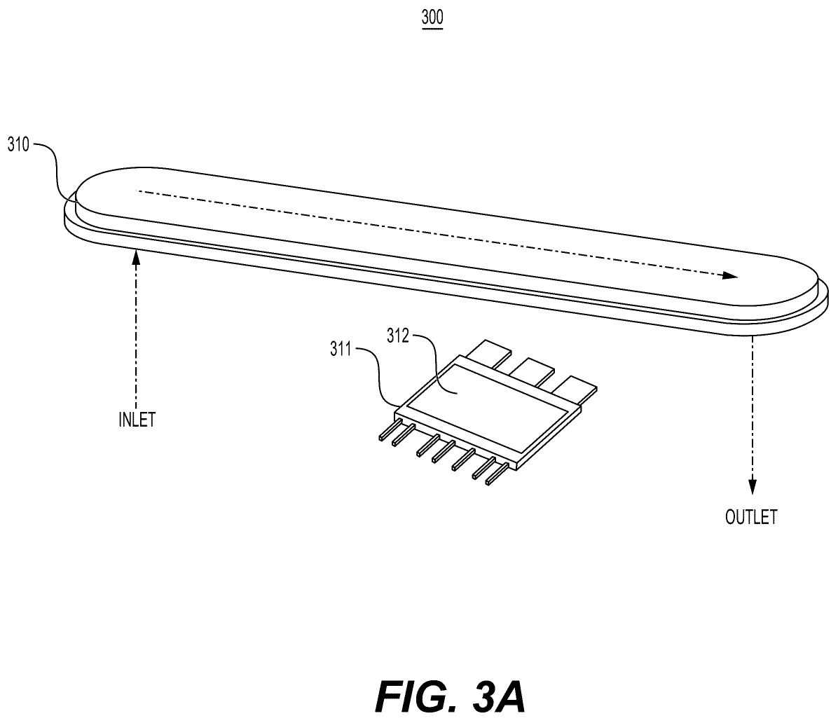

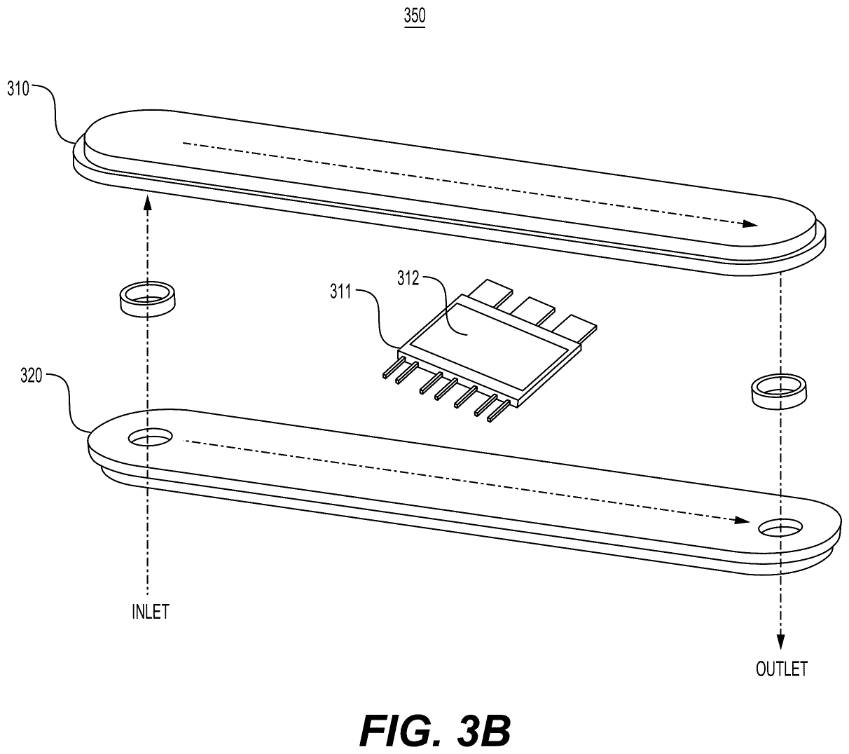

FIG. 3A depicts an exemplary cooling assembly including a first cooling module, a power module, and a thermal interface material (TIM) layer, according to one or more embodiments. Single-side cooling assembly 300 may include a first cooling module 310, a power module 311, and a thermal interface material (TIM) 312. The first cooling module 310 may correspond to the cooling module of FIG. 2, and the power module 311 may correspond to the power module 112 of FIG. 1.

The first cooling module 310 may include an inlet port and an outlet port (not depicted in FIG. 3A). Additionally, first cooling module 310 may have been laser ablated similar to cooling module 200 such that portions of the substrate are exposed. The inlet port may be configured to supply (or introduce) a flow of coolant to the first cooling module 310 and the outlet port may be configured to exhaust the flow of coolant in the first cooling module 310, which is depicted by the arrows in FIG. 3A.

The power module 311 has a first side surface and a second side surface. In one or more embodiments, the first cooling module 310 may be configured to be provided on the first side surface or the second side surface of the power module 311 (e.g., on a single side surface) to extract heat from the power module 311. Power module 311 may be mounted onto the exposed substrate 209 of cooling module 200 at one of the contact areas 214, 216, 218, 220, 222, and 224. In some embodiments, power modules are mounted at all of the contact areas 214, 216, 218, 220, 222, and 224 (e.g., six power modules).

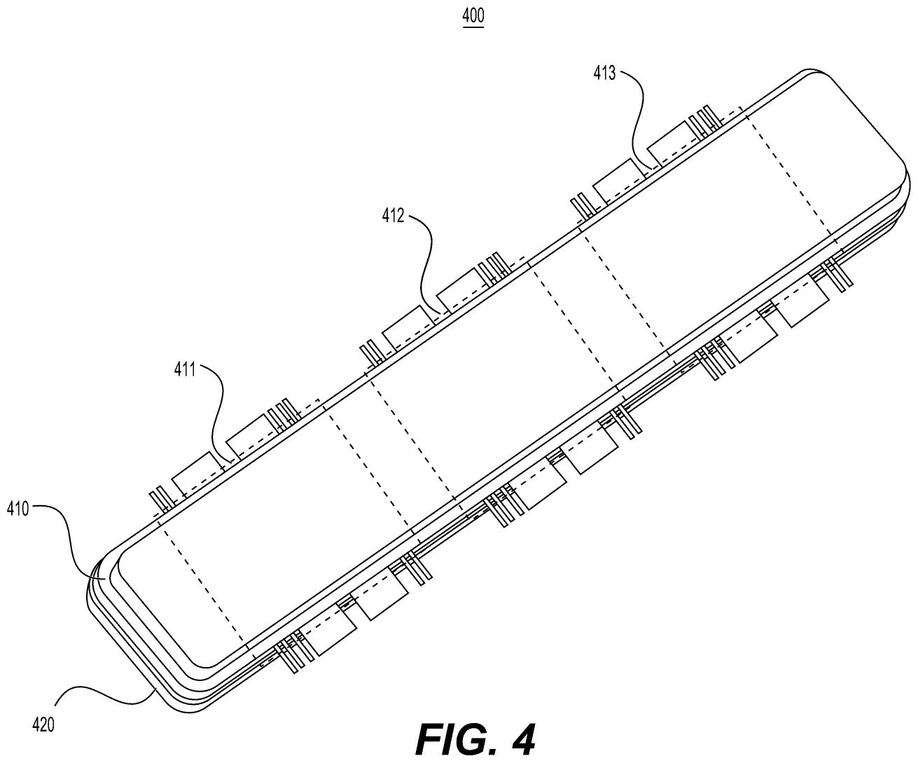

FIG. 3B depicts the cooling assembly of FIG. 3A with a second cooling module, according to one or more embodiments. Double-side cooling assembly 350 may include the first cooling module 310, a second cooling module 320, the power module 311, and the TIM 312. The first cooling module 310 and the second cooling module 320 may each correspond to the cooling module 200 of FIG. 2 and/or the cooling assembly (e.g., heat sink system) 400 of FIG. 4.

The first cooling module 310 may include an inlet port and an outlet port (not depicted in FIG. 3B). The inlet port may be configured to supply (or introduce) a flow of coolant to the first cooling module 310 and the outlet port may be configured to exhaust the flow of coolant in the first cooling module 310, which is depicted by the arrows in FIG. 3B.

The second cooling module 320 may include an inlet port and an outlet port (not depicted in FIG. 3B). The inlet port may be configured to supply (or introduce) a flow of coolant to the second cooling module 320 and the outlet port may be configured to exhaust the flow of coolant in the second cooling module 320, which is depicted by the arrows in FIG. 3B.

The flow of coolant supplied into the first cooling module 310 may be supplied from the inlet port of the second cooling module 320, but embodiments are not limited thereto. The flow of coolant exhausted through the outlet port of the first cooling module 310 may be exhausted to the outlet port of the second cooling module 320, and the outlet port of the second cooling module 320 may exhaust the flow of coolant exhausted by the first cooling module 310 and the flow of coolant in the second cooling module 320, but embodiments are not limited thereto.

The power module 311 has a first side surface and a second side surface. In one or more embodiments, the first cooling module 310 may be configured to be provided on a first side surface of the power module 311 (e.g., at a contact area) and the second cooling module 320 may be configured to be provided on a second side surface of the power module 311 (e.g., at a contact area) to extract heat from the power module 311.

FIG. 4 depicts an exemplary three-phase double-sided cooling assembly including a plurality of power modules, according to one or more embodiments. Three-phase double-side cooling assembly 400 may include a first cooling module (e.g., heat sink system) 410, a second cooling module (e.g., heat sink system) 420, and a plurality of power modules including a first power module 411, a second power module 412, and a third power module 413. The first cooling module 410 and the second cooling module 420 may each be the cooling module 200 of FIG. 2, the first cooling module 310 of FIG. 3A, and/or the second cooling module 320 of FIG. 3B. The plurality of power modules may correspond to power module 112 of FIG. 1. For brevity, the three-phase double-side cooling assembly 400 of FIG. 4 and the double-side cooling assembly 350 in FIG. 3B may contain many similarities which will not be discussed. For brevity of description, only distinctions between the three-phase double-side cooling assembly 400 and the double-side cooling assembly 350 will be described.

The plurality of power modules including the first power module 411, the second power module 412, and the third power module 413, may correspond to the power module 112 of FIG. 1. For example, the power module 112 may be a three-phase power module for a three-phase system. That is, in a three-phase system, the first power module 411 may correspond to ΦA, the second power module 412 may correspond to ΦB, and the third power module 413 may correspond to ΦC.

The first power module 411, the second power module 412, and the third power module 413 may each have a first side surface and a second side surface. The first cooling module 410 may be provided on the first side surface of the first power module 411, the first side surface of the second power module 412, and the first side surface of the third power module 413. The second cooling module 320 may be provided on the second side surface of the first power module 411, the second side surface of the second power module 412, and the second side surface of the third power module 413. That is, the three-phase double-side cooling assembly 400 may be configured to extract heat from both side surfaces of the plurality of power modules. In some embodiments, the first cooling module 410 and the second cooling module 420 may include laser ablated cutouts in the plating surrounding the substrate as described with respect to cooling module 200. The substrate exposed by the laser ablated cutouts may be in contact with and/or be soldered/sintered to TIM of the first power module 411, the second power module 412, and/or the third power module 413.

One or more embodiments may include a cooling module with a full plating that is selectively laser ablated. One or more embodiments may provide a quicker and more affordable process for preparing a cooling module. One or more embodiments may provide a more precise, e.g., better dimensionally controlled, substrate exposure for soldering areas. One or more embodiments may improve thermal performance by reducing thermal resistance. One or more embodiments may provide a solder stop around the exposed substrate to reduce hard TIM solder bleeding on a cooling module. One or more embodiments provide a cooling module without an applied protection layer, e.g., Organic Solderability Preservative (OSP).

Other embodiments of the disclosure will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A system comprising an inverter configured to convert DC power from a battery to AC power to drive a motor, wherein the inverter includes:
a first power module; and
a first cooling module configured to extract heat from the first power module, wherein the first cooling module includes:
a substrate including a first contact area for the first power module, and
a plating layer on the substrate, wherein the plating layer is removed from the first contact area of the substrate using laser ablation.

2. The system of claim 1, wherein the first cooling module further includes:
a thermal interface material between the first power module and the first contact area of the substrate.

3. The system of claim 2, wherein:
the thermal interface material includes a solder layer, and
the plating layer provides a solder stop for the solder layer.

4. The system of claim 1, wherein the first cooling module further includes:
a second contact area for a second power module, wherein the plating layer is removed from the second contact area of the substrate using laser ablation.

5. The system of claim 4, wherein the first contact area is separated from the second contact area by the plating layer.

6. The system of claim 4, wherein the first cooling module further includes:
a third contact area for a third power module,
a fourth contact area for a fourth power module,
a fifth contact area for a fifth power module, and
a sixth contact area for a sixth power module,
wherein the plating layer is removed from each of the third contact area, the fourth contact area, the fifth contact area, and the sixth contact area of the substrate using laser ablation.

7. The system of claim 1, wherein the substrate includes copper and the plating layer includes nickel.

8. The system of claim 1, wherein:
the inverter further includes:
a second cooling module;
a second power module; and
a third power module,
the first cooling module is provided on a first side surface of the first power module, a first side surface of the second power module, and a first side surface of the third power module, and
the second cooling module is provided on a second side surface of the first power module, a second side surface of the second power module, and a second side surface of the third power module.

9. The system of claim 1, wherein the plating layer is not removed from the first contact area of the substrate using selective plating.

10. The system of claim 1, wherein the plating layer protects the substrate from corrosion.

11. The system of claim 1, further comprising:
the battery configured to supply the DC power to the inverter; and
the motor configured to receive the AC power from the inverter to drive the motor, wherein the system is provided as a vehicle including the inverter, the battery, and the motor.

12. A system comprising a cooling module configured to extract heat from a power module, wherein the cooling module includes:
a substrate including a contact area for a power module, and
a plating layer on the substrate, wherein the plating layer is removed from the contact area of the substrate using laser ablation.

13. The system of claim 12, wherein the cooling module is maintained at a temperature below 150 degrees Celsius during the laser ablation.

14. The system of claim 12, wherein a surface roughness of the substrate in the contact area is less than 2 micrometers.

15. The system of claim 12, wherein the cooling module further includes:
a solder layer on the contact area of the substrate, wherein the plating layer provides a solder stop for the solder layer.

16. A method comprising:
applying a plating layer to a surface of a substrate of a cooling module; and
removing, using laser ablation, a first portion of the plating layer from the substrate to expose a first contact area of the substrate for mounting a first power module to the first contact area.

17. The method of claim 16, further comprising:
applying a sinter layer to the first contact area.

18. The method of claim 17, further comprising:
applying the sinter layer to the first contact area without applying a protection layer to the first contact area.

19. The method of claim 17, further comprising:
mounting the first power module to the sinter layer.

20. The method of claim 17, further comprising:
removing, using laser ablation, a second portion of the plating layer from the substrate to expose a second contact area of the substrate for mounting a second power module to the second contact area,
wherein the first contact area is separated from the second contact area by the plating layer.
